(19) United States
(12) Patent Application Publication
(10) Pub. No.: US 2026/0150721 A1
(43) Pub. Date: May 28, 2026

(54) MULTI-PACKAGE FABRIC ON PRINTED CIRCUIT BOARD USING BRIDGE PACKAGE

(71) Applicant: FlexAI, SAS, Paris (FR)

(72) Inventors: Sameer Vinayak Mahajan, Maharashtra (IN); Yogasundaram Chandiran, Tamilnadu (IN); Praveen Basty Pai, Karnataka (IN); Brijesh Tripathi, Los Altos, CA (US)

(21) Appl. No.: 19/064,512

(22) Filed: Feb. 26, 2025

Related U.S. Application Data
(60) Provisional application No. 63/724,186, filed on Nov. 22, 2024.

(51) Int. Cl. H01L 23/538; H01L 21/48; H01L 23/04; H01L 25/00; H01L 25/03

(52) U.S. Cl. CPC H10W 70/611; H10W 70/05; H10W 90/00; H10W 90/401; H10W 76/12

(57) ABSTRACT

This disclosure provides an electronic system and a method of fabricating an electronic system. The electronic system comprises a printed circuit board (PCB), and a plurality of electronic packages disposed on the PCB and having electrical connections to conductors of the PCB. The electronic system comprises at least one bridge package. Each bridge package of the at least one bridge package electrically connects two adjacent electronic packages of the plurality of electronic packages to thereby facilitate direct communication between the two adjacent electronic packages.

### CROSS-REFERENCE TO RELATED APPLICATIONS

This application claims benefit of provisional U.S. Patent Application No. 63/724,186, filed Nov. 22, 2024, which is incorporated herein by reference in its entirety.

### TECHNICAL FIELD

Embodiments of the present disclosure relate generally to electronic systems. More particularly, embodiments of the disclosure relate to multiple packages'connection in the electronic systems.

### BACKGROUND

With the continued growth of AI computing (training and/or inference) and/or high performance computing (HPC) systems, improved connectivity between multiple packages is important. An electronic systems, such as a microelectronic device, may include multiple packages disposed on a printed circuit board (PCB). Within one package, there may be multiple dies within one substrate which are connected to each other. The electrical communication from one package to the other package is important. Improvements in the electrical connection of multiple packages provides better package-package bandwidth and improved performance.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

With the continued growth of AI computing (training and/or inference) and/or high performance computing (HPC) systems, improved connectivity between multiple packages is important. Multiple packages may be disposed on the PCB in an electronic system. Die-die (D-D) Intellectual property (IP) may allow long reach connections through standard packaging. The multiple packages may be electrically connected through second-level interconnects such as ball grid arrays (BGAs) on the bottom sides (back) of the multiple packages. A ball grid array (BGA) package is a type of surface-mount packaging that includes an array of solder balls on the underside, which serve as electrical connections to the PCB. However, by using the connection through the BGAs, the length of the connection is much longer to connect through the PCB, which may cause power, performance and cost issues.

Aspects of the present disclosure address the above-noted and other deficiencies by using a bridge package to electrically connect multiple packages, expanding and connecting the multiple packages crossing the boundary of each individual package through the bridge package. Thus, a board-level package fabric (like wafer-level die fabric) for AI computing (training and/or inference) and/or high performance computing (HPC) systems is developed. The board-level architecture that enables continuous connectivity across multiple packages is created to achieve better package-package bandwidth connectivity than that through the second-level interconnects such as BGA. In this way, large scale up to panel-level products are enabled. The technologies disclosed herein provides higher package edge bandwidth per mm, with the modular and scalable functionality. By using the bridge package, it provides cost efficient architecture. As die-die signals do not require second-level interconnects, those interconnects may be utilized for power delivery and/or placing land side components (LSC) when using the bridge package connection. The multiple packages may directly communicate with each other through the bridge package(s). The communication between the multiple packages do not rely on input/output (I/O) signals which have to go through the PCB. Through minimization of the input/output (I/O) chiplets, the power consumption and the cost of the electronic system are reduced. The signal performance is improved by reducing the noise, and improving the signal strength, as the multiple packages are electrically connected in the signal layer level, without going through the connection via the PCB.

According to some aspects, an electronic system is disclosed. The electronic system comprises a printed circuit board (PCB), and a plurality of electronic packages disposed on the PCB and having electrical connections to conductors of the PCB. The electronic system comprises at least one bridge package. Each bridge package of the at least one bridge package electrically connects two adjacent electronic packages of the plurality of electronic packages to thereby facilitate direct communication between the two adjacent electronic packages.

According to some aspects, a method of fabricating an electronic system is disclosed. The method comprises disposing a plurality of electronic packages on a printed circuit board (PCB). The plurality of electronic packages having electrical connections to conductors of the PCB. The method comprises disposing at least one bridge package. Each bridge package of the at least one bridge package electrically connects two adjacent electronic packages of the plurality of electronic packages to thereby facilitate direct communication between the two adjacent electronic packages.

### BRIEF DESCRIPTION OF THE DRAWINGS

FIG. 1 illustrates a diagram of an example of a top view of an assembled printed circuit board (PCB) with multiple packages and at least one bridge package according to some embodiments.

FIG. 2 illustrates a diagram of an example of a side view of an assembly PCB with multiple packages and at least one bridge package according to some embodiments.

FIGS. 3A-3F illustrate examples 300a, 300b, 300c, 300d, 300e, 300f of cross sectional views of different bridge package types according to some embodiments.

FIGS. 4A-4C illustrate examples of cross section views of a multi-package fabric with a bridge package on a PCB according to some embodiments.

FIGS. 5A-5C illustrate examples of cross section views of a multi-package fabric with a bridge package on a PCB with thermal solution according to some embodiments.

FIG. 6 is a flowchart of a method of fabricating an electronic system according to some embodiments.

### DETAILED DESCRIPTION

Various embodiments and aspects of the disclosure will be described with reference to details discussed below, and the accompanying drawings will illustrate the various embodiments. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

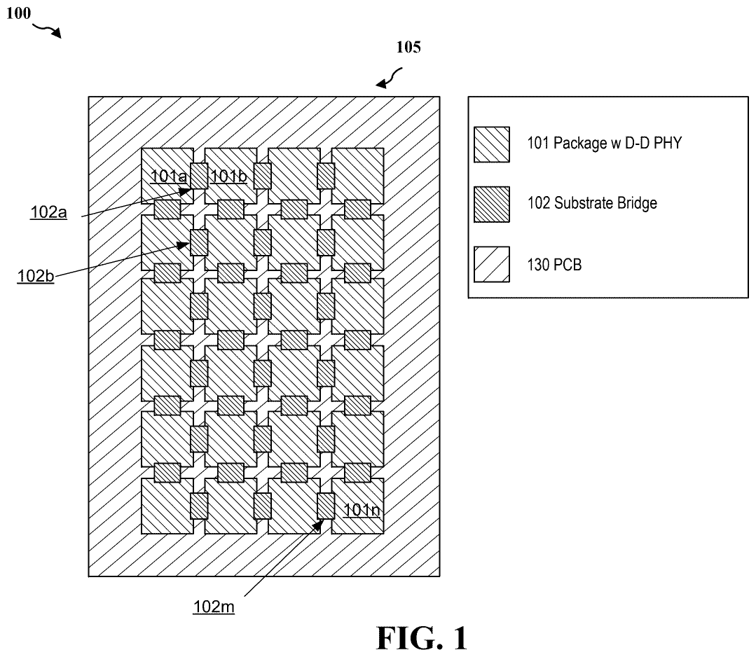

FIG. 1 illustrates a diagram of an example of a top view 100 of an assembled PCB with multiple packages and at least one bridge package according to some embodiments. As illustrated in FIG. 1, a fabric of multiple packages are connected to each other by one or more bridge packages. In this example, the die on one package is connected to the die on another package through a bridge package. Depending on the product requirements, single or multiple package designs may be connected to each other with single or multiple bridge package designs. These packages may be of different packaging technologies such as standard package (2-dimensional) or advanced package (2.x dimensional or 3.x dimensional).

Referring to FIG. 1, the electronic system 105 includes a PCB 130, and a plurality of electronic packages (e.g., 101a, 101b, . . . , 101n) disposed on the PCB 130 and having electrical connections to conductors of the PCB. The electronic system 105 includes at least one bridge package (e.g., 102a, 102b, . . . , 102m). Each bridge package of the at least one bridge package electrically connects two adjacent electronic packages of the plurality of electronic packages to thereby facilitate direct communication between the two adjacent electronic packages. The multiple packages (e.g., 101a, 101b, . . . , 101n) are disposed on the PCB 130, which are connected to each other by bridge packages (e.g., 102a, 102b, . . . , 102m). The one or more bridge packages (e.g., 102a, 102b, . . . , 102m) are used to electrically connect the multiple packages, expanding and connecting the multiple packages crossing the boundary of each individual package through the at least one bridge package. The multiple packages include different types of packages, for example, packages with die-die (D-D) Intellectual property (IP) (e.g., 101a, 101b, . . . , 101n), which may allow long reach connections through standard packaging. The bridge package (e.g., 102a, 102b, . . . , 102m) may be used to connect two adjacent packages of the multiple packages, for example, two D-D IP packages, or other types of packages.

With the continued growth of AI computing (training and/or inference) and/or high performance computing (HPC) systems, improved connectivity between multiple packages is important. By using the bridge package, a board-level package fabric (like wafer-level die fabric) for AI computing (training and/or inference) and/or high performance computing (HPC) systems is developed. The board-level architecture that enables continuous connectivity across multiple packages is created to achieve better package-package bandwidth connectivity than that through the second-level interconnects such as BGAs. In this way, large scale up to panel-level products are enabled. The technologies disclosed herein provides higher package edge bandwidth per mm, with the modular and scalable functionality. By using the bridge package, it provides cost efficient architecture. As die-die signals do not require second-level interconnects, those interconnects may be utilized for power delivery and/or de-poped to place land side components (LSC) when using the bridge package connection. The multiple packages may directly communicate with each other through the bridge package(s). The communication between the multiple packages do not rely on input/output (I/O) signals which have to go through the PCB. Through minimization of the input/output (I/O) chiplets, the power consumption and the cost of the electronic system are reduced. The signal performance is improved by reducing the noise, and improving the signal strength and signal to noise ratio, as the multiple packages are electrically connected in the signal layer level, without going through the connection via the PCB. By using the bridge package, the input/output (I/O) chip count requirements is reduced, the power associated with input/output (I/O) chip count requirements is reduced, and the requirements for second-level interconnect side allowing space for land side component (LSC) and/or second-level interconnect pitch are relaxed.

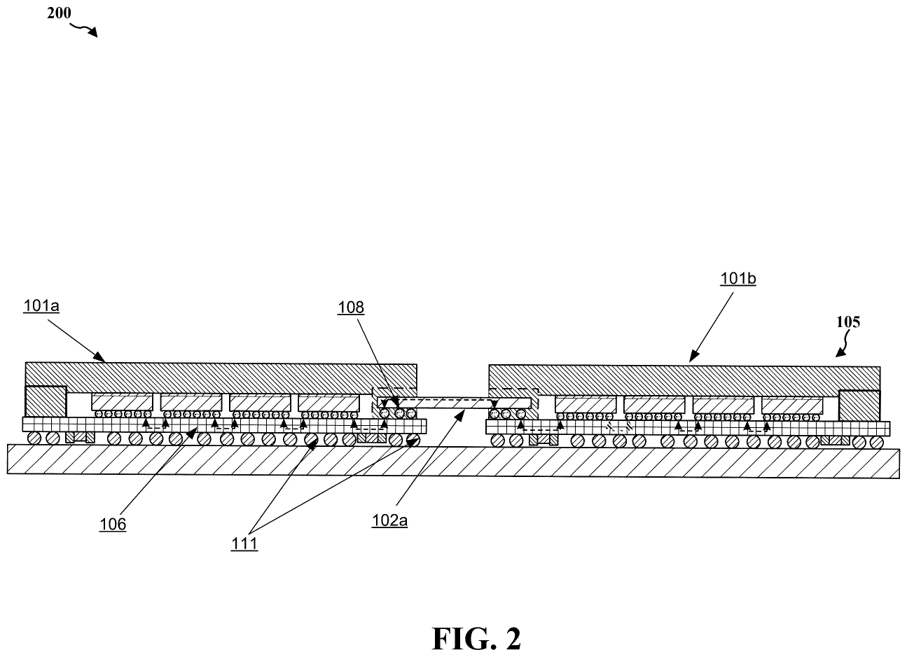

FIG. 2 illustrates a diagram of an example of a side view 200 of the assembled PCB 105 with multiple packages and at least one bridge package according to some embodiments. Substrate bridges can enable the same or different material than that of the main package depending on various design requirements such as electrical, mechanical, thermo-mechanical, assembly, and reliability. The substrate layer of the main package can be made from a variety of materials, including fiberglass, glass fiber reinforced epoxy, FR-4, glass, Kapton, Aluminum or ceramic, polyimide, Teflon, build-up dielectric etc. The Substrate bridges may use the same materials as the substrate layer of the main package including fiberglass, glass fiber reinforced epoxy, FR-4, glass, Kapton, Aluminum or ceramic, polyimide, Teflon, build-up dielectric etc.

Referring to FIG. 2, for each bridge package, a bridge package (e.g., 102a) is disposed substantially over a gap of two adjacent electronic packages (e.g., 101a, 101b). As an example, the bridge package 102a may be a substrate package, which may use the same material, similar construction, and/or similar design of the substrate of the multiple packages 101a, 101b. For the multiple packages, there may be silicon dies on top of the substrate. The multiple packages 101a, 101b may have layered construction. In some examples, the bridge package (e.g., 102a) is a pass through circuitry that connects to two packages, and the bridge package 102a includes the substrate but does not have a die on top of the substrate. In some examples, the bridge package 102a has a die or a chip on top of the substrate.

Using the bridge package (e.g., 102a) allows dies on multiple packages (e.g., 101a, 101b) to directly communicate with each other, instead of routing die-die (D-D) physical layer (PHY) connections to second-level interconnect pins or BGAs 111 on the backside of the multiple packages. The bridge interconnects 108 of the bridge package are routed to the front side (top side) of the substrate 106 in the signal layer. In order to utilize regular PCB assembly processes, the bridge interconnect pitch may be larger compared to that of D-D physical layer (PHY) IP connections. The substrate bridges are designed such that quality and reliability requirements are met. The substrate bridges can be coreless or with core.

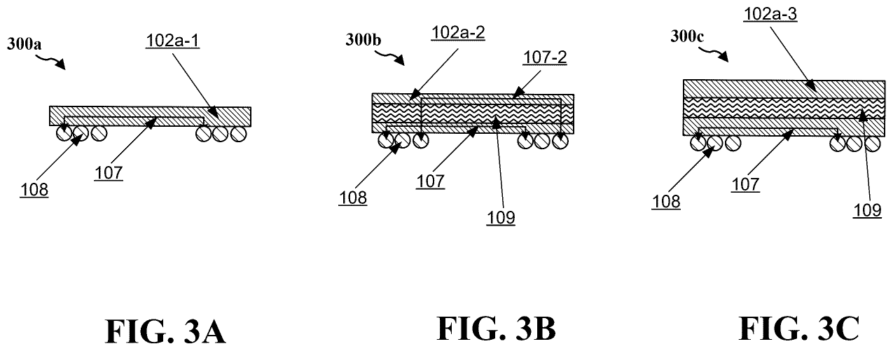

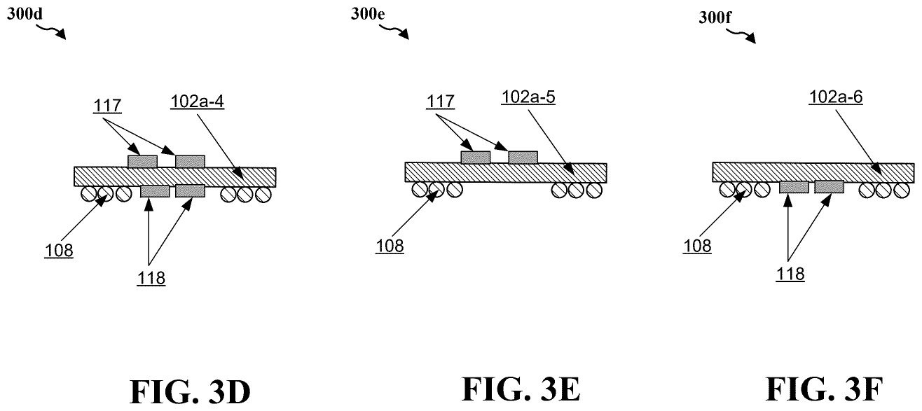

FIGS. 3A-3F illustrate examples 300a, 300b, 300c, 300d, 300e, 300f of cross sectional views of different bridge package types according to some embodiments. These configurations of the bridge package may be implemented based on requirements of the product. The bridge package may be a multi-layer package with coreless architecture or with core architecture, where different core types may be implemented.

Referring to FIG. 3A, a bridge package 102a-1 may be coreless, which does not include a stiff core. The bridge package 102a-1 includes the substrate (e.g., build-up dielectric), a copper wire 107 and interconnect BGA 108, which electrically connect the bridge package to the main packages (e.g., 101a, 101b) on the PCB. The bridge package may be without any component or chip.

Referring to FIG. 3B, a bridge package 102a-2 may include a stiff core 109. The bridge package 102a-2 includes the substrate (e.g., build-up dielectric), the core 109, a copper wire 107 which runs below the core 109, a copper wire 107-2 which runs across the core 109, and interconnect BGA 108, which electrically connect the bridge package to the main packages (e.g., 101a, 101b) on the PCB. The bridge package may be without any component or chip.

Referring to FIG. 3C, a bridge package 102a-3 may include the stiff core 109. The bridge package 102a-3 includes the substrate (e.g., build-up dielectric), the core 109, a copper wire 107 which runs below the core 109, and interconnect BGA 108, which electrically connect the bridge package to the main packages (e.g., 101a, 101b) on the PCB. The bridge package may be without any component or chip.

Referring to FIG. 3D, a bridge package 102a-4 may have a component and/or chip 117, 118 on both sides of the package. The component and/or chip 117 may be disposed on a front side of the bridge package 102a-4. The component and/or chip 118 may be disposed on a back side of the bridge package 102a-4.

Referring to FIG. 3E, a bridge package 102a-5 may have the component and/or chip 117 on the front side of the bridge package 102a-5. Referring to FIG. 3F, a bridge package 102a-6 may have the component and/or chip 118 on the back side of the bridge package 102a-6.

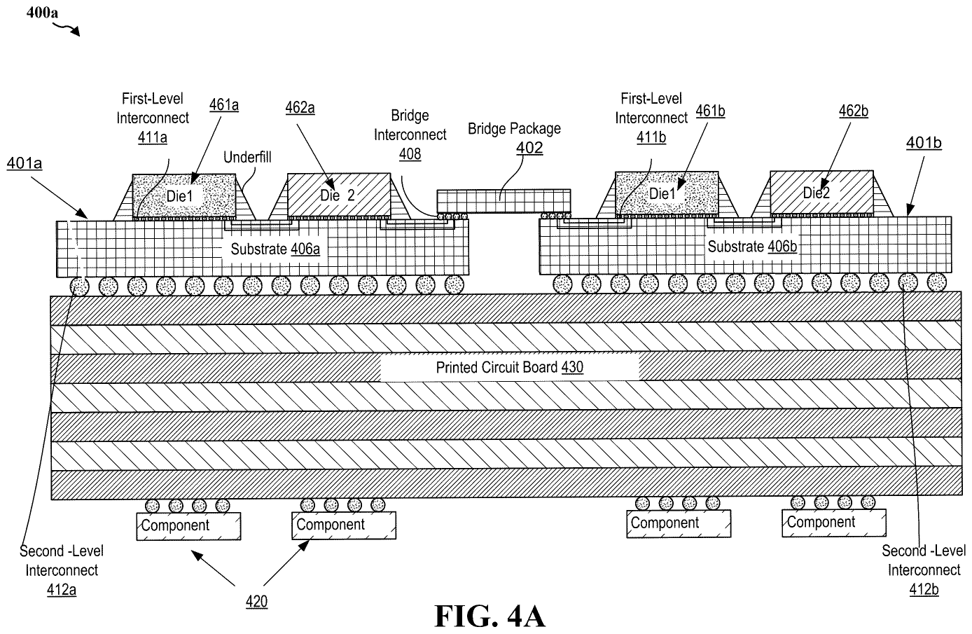

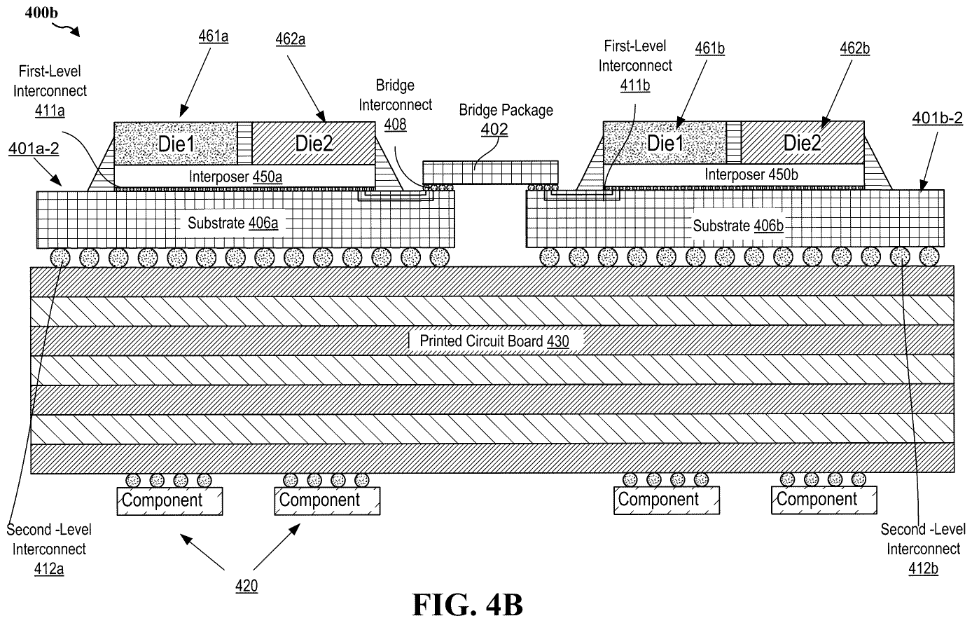

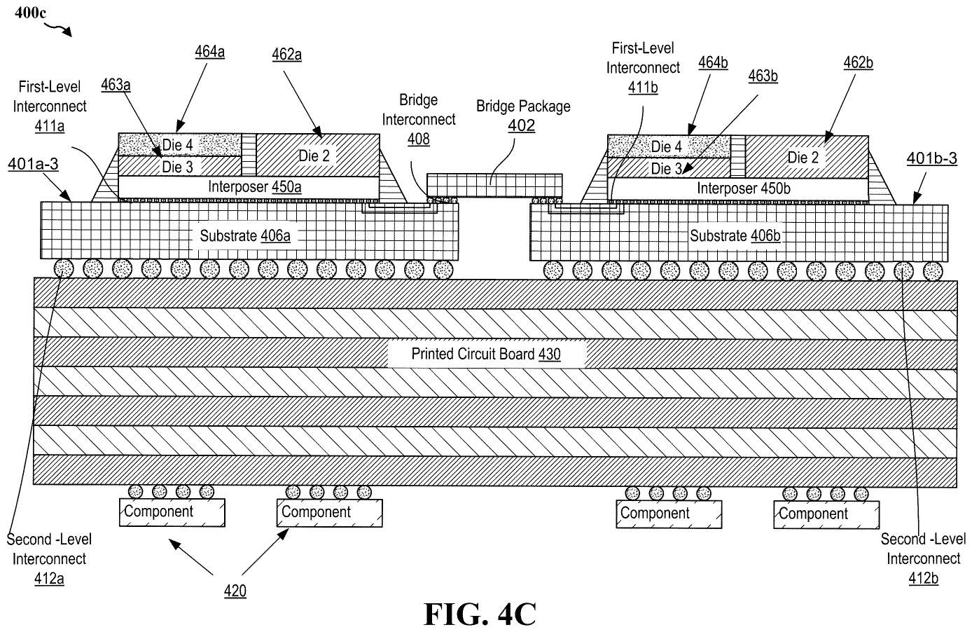

FIGS. 4A-4C illustrate examples of cross section views of a multi-package fabric with a bridge package on a PCB according to some embodiments. FIG. 4A illustrates an example 400a of the cross sectional view of two packages 401a, 401b assembled on the PCB 430 and connected with the bridge package 402 creating the multi-package fabric. In a first package 401a, die 1 461a and die 2 462a are assembled on top of a substrate 406a with first-level interconnects 411a. Die 1 461a and die 2 462a design may be either same or different. Underfill is dispensed surrounding the first-level interconnects 411a. Similarly, in a second package 401b, die 1 461b and die 2 462b are assembled on top of a substrate 406b with first-level interconnects 411b. Die 1 461b and die 2 462b design may be either same or different. Underfill is dispensed surrounding the first-level interconnects 411b. In this example, two bare die packages 401a, 401b are assembled on top of the PCB 430 with second-level interconnects 412a, 412b and have electrical connections to conductors of the PCB 430. The bridge package 402 is used to connect the two packages 401a, 401b through bridge interconnects 408 on the top side of the substrates 406a, 406b. As shown in FIG. 4A, the bridge interconnects 408 of the bridge package 402 may be electrically connected with the first-level interconnects 411a on a front side of the substrate 406a in the first package 401a and electrically connected with the first-level interconnects 411b on a front side of the substrate 406b in the second package 401b.

The bridge package 402 may be either of the same type as the substrates 406a or 406b, or it may be of a different type to meet functional and manufacturing requirements of the product. The two packages 401a, 401b can be similar or dissimilar in design. The two adjacent electronic packages 401a, 401b are connected through the bridge interconnects 408 of the bridge package 402. The bridge interconnects 408 directly connect with the first-level interconnects 411a, 411b of the two adjacent electronic packages 401a, 401b on the front side of substrates 406a, 406b of the two adjacent electronic packages. The PCB 430 may have component 420 on the back side for electrical connection.

FIG. 4B illustrates another example 400b of a cross sectional view of two packages 401a-2, 401b-2 assembled on the PCB 430 and connected with the bridge package 402 creating a multi-package fabric. In a single package 401a-2, die 1 461a and die 2 462a are assembled on top of an interposer 450a, which is connected with the substrate 406a with first-level interconnects 411a. For example, an interposer is multi-layer circuit of either silicon or organic material that acts as a bridge between chips or dies in semiconductor technology. In a single package 401b-2, die 1 461b and die 2 462b are assembled on top of an interposer 450b, which is connected with the substrate 406b with first-level interconnects 411b. The bridge package 402 is used to connect the two packages 401a-2, 401b-2 through bridge interconnects 408 on the top side of the substrates 406a, 406b.

FIG. 4C illustrates another example 400c of a cross sectional view of two packages 401a-3, 401b-3 assembled on the PCB 430 and connected with the bridge package 402. As illustrated in FIG. 4C, two 3.x-Dimensional packages 401a-3, 401b-3 may be assembled on the PCB 430 and connected with the bridge package 402 creating a multi-package fabric. In a single package 401a-3, die 3 463a, and die 4 464a are 3-dimensional stack, and assembled on top of an interposer 450a with die 2 462a, which is connected with the substrate 406a with first-level interconnects 411a. In a single package 401b-3, die 3 463b, and die 4 464b are 3-dimensional stack, and assembled on top of an interposer 450b with die 2 462b, which is connected with the substrate 406b with first-level interconnects 411b. The bridge package 402 is used to connect the two packages 401a-3, 401b-3 through bridge interconnects 408 on the top side of the substrates 406a, 406b. Underfill is dispensed surrounding the first-level interconnects 411a and 411b. In this example, two 3.x-Dimensional packages 401a-3, 401b-3 of the multiple packaged are assembled on top of the PCB 430 with second-level interconnects 412a and 412b. The bridge package 402 is used to connect the two 3.x-Dimensional packages 401a-3, 401b-3 through the bridge interconnects 408. The two 3.x-Dimensional packages 401a-3, 401b-3 can be similar or dissimilar in configuration.

As illustrated in FIGS. 4A-4C, though each package of the adjacent packages (e.g., 401a, 401b) has the second-level interconnects 412a, 412b (e.g., ball grid array), on the back side of the substrate 406a and 406b, connected to the PCB 430, the bridge package 402 is not connected to the second-level interconnects 412a, 412b, but is connected through the bridge interconnects 408 on the top side (front side) of the substrate 406a and 406b. The bridge interconnects 408 directly connects with the first-level interconnects 411a, 411b of the two packages (e.g., 401a, 401b) in the signal layer on the front side (top side) of the substrates 406a, 406b.

By using the bridge package, the communication signals between the two adjacent packages travel in the top layers of the substrates 406a, 406b. The electrical connection between the two packages 401a, 401b are through the bridge interconnects 408.

There are different assembly processes for the bridge interconnects. One type of assembly process is solder reflow process using the same material that is used as second-level interconnect for the substrate 406a, 406b of the main packages 401a, 401b. The bridge interconnects 108 may include BGAs made of either the same material of the BGA of the main packages 401a, 401b or different material. Another type of process may be silver sintering, which is a heat-treatment process applied to a powder material. The silver sintering is reliable technology for connecting components in power electronics. For example, silver-sintering paste may be used. Another type of process is anisotropic conductive film process, or the use of anisotropic conductive film (ACF), which involves a series of steps to create a conductive bond between two surfaces.

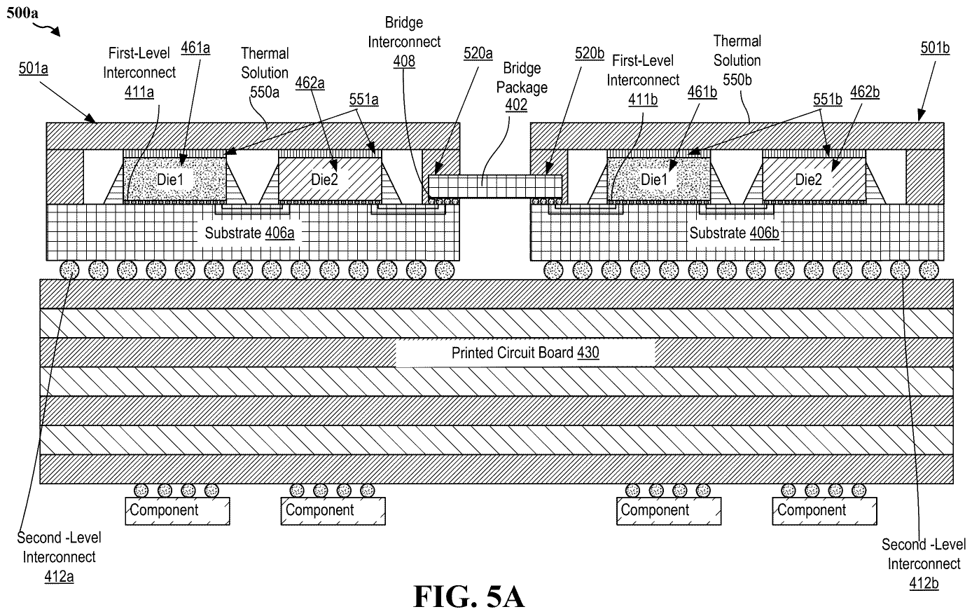

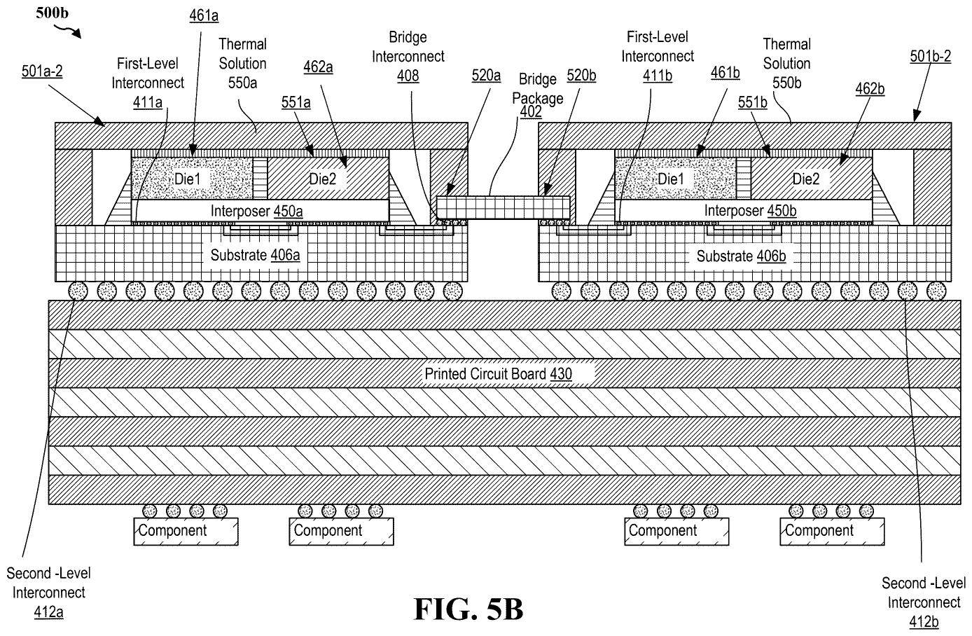

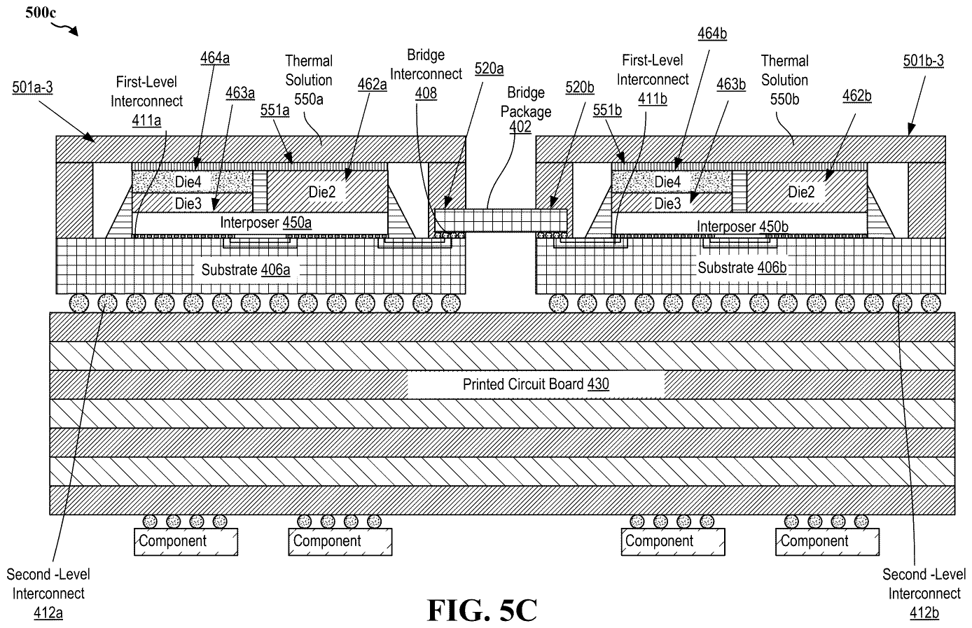

FIGS. 5A-5C illustrate examples of cross section views of a multi-package fabric with a bridge package on a PCB with thermal solution according to some embodiments. FIG. 5A illustrates an example 500a of a cross section view of a multi-package fabric with a bridge package on a PCB with thermal solution. Referring to FIG. 5A, the architecture in this example is similar as illustrated in FIG. 4A, except the use of thermal solution 550a, 550b on packages 501a, 501b, respectively. The thermal solution on the package 501a is disposed with a cut out 520a, and the thermal solution on the package 501b is disposed with a cut out 520b, such that bridge package 402 does not interfere with the thermal solution during assembly. In the first package 501a, Die 1 461a and Die 2 462a are assembled on top of the substrate 406a with first-level interconnects 411a. In the second package 501b, Die 1 461b and Die 2 462b are assembled on top of the substrate 406b with first-level interconnects 411b. Underfill is dispensed surrounding the first-level interconnects 411a and 411b. In this example, two packages 501a, 501b of the multiple packages are assembled on top of the PCB 430 with second-level interconnects 412a, 412b, respectively. The bridge package 402 is used to connect the two packages 501a, 501b through the bridge interconnects 408. Thermal solution 550a, 550b may be applied to the packages 501a, 501b with thermal interface material (TIM) 551a, 551b on top of the dies (e.g., Die 1 461a and Die 2 461a, Die 1 461b and Die 2 462b). These packages 501a, 501b can be similar or dissimilar in design.

FIG. 5B illustrates another example 500b of a cross section view of a multi-package fabric with a bridge package on a PCB with thermal solution. Referring to FIG. 5B, the architecture of this example is similar as shown in FIG. 5A, except the use of 2.x-dimensional packages to create the multi-package fabric. In the first package 501a-2, Die 1 461a and Die 2 462a are packaged together using advanced packaging technology such as the interposer 450a. In the second package 501b-2, Die 1 461b and Die 2 462b are packaged together using advanced packaging technology such as the interposer 450b. As illustrated in FIG. 5B, the bridge package 402 may be implemented using different types of packages. In the first package 501a-2, Die 1 461a and Die 2 462a are assembled on top of the interposer 450a, which is connected with the substrate 406a by the first-level interconnects. Underfill is dispensed surrounding the first-level interconnects 411a. In the second package 501b-2, Die 1 461b and Die 2 462b are assembled on top of the interposer 450b, which is connected with the substrate 406b by the first-level interconnects 411b. Underfill is dispensed surrounding the first-level interconnects 411a. In this example, two packages 501a-2, 501b-2 of these multiple packages are assembled on top of the PCB 430 with the second-level interconnects 412a, 412b respectively. The bridge package 402 is used to connect the two packages 501a-2, 501b-2 through the bridge interconnects 408. Thermal solution 550a, 550b may be applied to the packages 501a-2, 501b-2 with TIM 551a, 551b on top of the dies (e.g., Die 1 461a and Die 2 462a, Die 1 461b and Die 2 462b). These packages 501a-2, 501b-2 can be similar or dissimilar in design.

FIG. 5C illustrates another example 500c of a cross section view of a multi-package fabric with a bridge package on a PCB with thermal solution. Referring to FIG. 5C, the architecture of this example is similar as shown in FIG. 5B, except the use 3.x-dimensional packages to create multi-package fabric. Die 3 (463a, or 463b) and Die 4 (464a, or 464b) are 3-dimensional stacked and packaged together with Die 2 (462a, or 462b) using advanced packaging technology such as interposer (450a, or 450b) in this case. As illustrated in FIG. 5C, the bridge package 402 may be implemented using different types of packages. In the first package 501a-3, Die 4 464a, and Die 3 463a are 3-dimensional stacked and assembled on top of the interposer 450a with Die 2 462a, which is connected with the substrate 406a by the first-level interconnects 411a. In the second package 501b-3, Die 4 464b, and Die 3 463b are 3-dimensional stacked and assembled on top of the interposer 450b with Die 2 462b, which is connected with the substrate 406b by the first-level interconnects 411b. Underfill is dispensed surrounding the first-level interconnects 411a, 411b. In this example, two packages 501a-3, 501b-3 of these packages are assembled on top of the PCB 430 with the second-level interconnects 412a, 412b, respectively. The bridge package 402 is used to connect the two packages 501a-3, 501b-3 through the bridge interconnects 408. Thermal solution 550a, 550b may be applied to the packages 501a-3, 501b-3 with TIM 551a, 551b on top of the dies (e.g., Die 4 464a, Die 2 462a and Die 3 463a, Die 4 464b, Die 2 462b and Die 3 463b). These packages 501a-3, 501b-3 can be similar or dissimilar in design. Different package architecture may be combined on the same PCB.

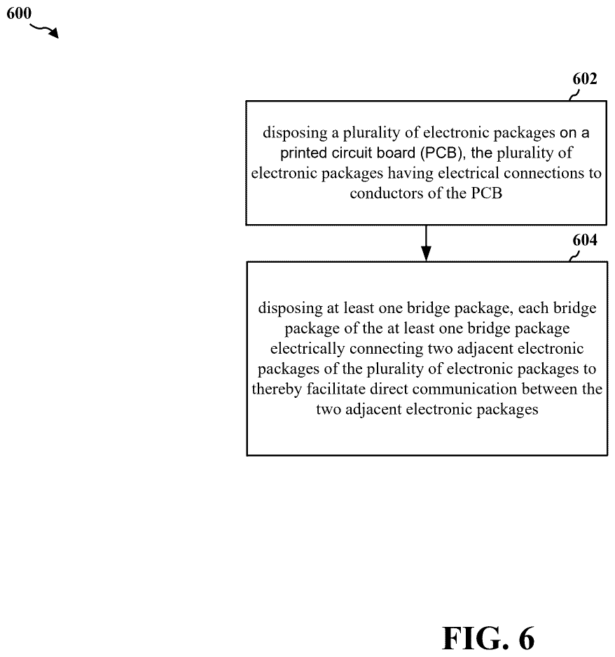

FIG. 6 is a flowchart of a method of fabricating an electronic system according to some embodiments. The method includes disposing 602 a plurality of electronic packages on a PCB. The plurality of electronic packages having electrical connections to conductors of the PCB.

The method includes disposing 604 at least one bridge package. Each bridge package of the at least one bridge package electrically connects two adjacent electronic packages of the plurality of electronic packages to thereby facilitate direct communication between the two adjacent electronic packages. In some examples, the method may further include, for each bridge package, disposing a bridge package substantially over a gap of two adjacent electronic packages; electrically connecting the bridge package with a first electronic package of the two adjacent electronic packages and a second electronic package of the two adjacent electronic packages.

There are several options in fabricating the electronic system including multiple packages connected by using the bridge package(s). In some examples, the main packages may be placed on the PCB, then the bridge package may be placed on main packages. Then the reflow fabrication may be applied. The reflow fabrication is a process that uses controlled heat to attach electrical components to a PCB. The reflow fabrication may be referred to as reflow soldering. After the bridge package is placed on top of the main packages, the entire board with all the multiple packages and the bridge packages(s) may be heated up. In this way, all the joints are formed at the same time.

In some examples, the main packages may be placed on the PCB, then the reflow fabrication may be applied. Afterwards, the bridge package may be placed on main packages, then the reflow fabrication may be applied again one more time. The attachment process may be split into two steps. The main packages may be heated first, until all joints in the main packages are formed. Then the bridge package may be placed on top of the main packages, and then the second reflow fabrication may be applied, in which the joints between the bridge package(s) and the main packages may be formed.

In some examples, the main packages may be placed on the PCB, then the reflow fabrication may be applied. Afterwards, the bridge package may be placed on main packages by using thermo-compression type bonding locally. Instead of using the reflow fabrication to heat up the entire board the second time, the heat and pressure may be applied locally by apply the thermo-compression type bonding to attach the bridge package(s) to the main packages. The above examples may be used to fabricate the bridge interconnects similar to the BGAs.

The specific order or hierarchy of blocks in the processes and flowcharts disclosed herein is an illustration of example approaches. Hence, the specific order or hierarchy of blocks in the processes and flowcharts may be rearranged. Some blocks may also be combined or deleted. Dashed lines may indicate optional elements of the diagrams. The accompanying method claims present elements of the various blocks in an example order, and are not limited to the specific order or hierarchy presented in the claims, processes, and flowcharts.

The detailed description set forth herein describes various configurations in connection with the drawings and does not represent the only configurations in which the concepts described herein may be practiced. The detailed description includes specific details for the purpose of providing a thorough explanation of various concepts. However, these concepts may be practiced without these specific details. In some instances, well known structures and components are shown in block diagram form in order to avoid obscuring such concepts.

Aspects of electronic systems are presented with reference to various apparatuses and methods. These apparatuses and methods are described in the following detailed description and are illustrated in the accompanying drawings by various blocks, components, circuits, processes, call flows, systems, algorithms, etc. (collectively referred to as “elements”). These elements may be implemented using electronic hardware, computer software, or combinations thereof. Whether such elements are implemented as hardware or software depends upon the particular application and design constraints imposed on the overall system.

Aspects, implementations, and/or use cases described herein may be implemented across many differing platform types, devices, systems, shapes, sizes, and packaging arrangements. For example, the aspects, implementations, and/or use cases may come about via integrated chip implementations and other non-module-component based devices, such as end-user devices, vehicles, communication devices, computing devices, industrial equipment, retail/purchasing devices, medical devices, artificial intelligence (AI)-enabled devices, machine learning (ML)-enabled devices, etc. The aspects, implementations, and/or use cases may range from chip-level or modular components to non-modular or non-chip-level implementations, and further to aggregate, distributed, or original equipment manufacturer (OEM) devices or systems incorporating one or more techniques described herein.

The description herein is provided to enable a person skilled in the art to practice the various aspects described herein. Various modifications to these aspects will be readily apparent to those skilled in the art, and the generic principles defined herein may be applied to other aspects. Thus, the claims are not limited to the aspects described herein, but are to be interpreted in view of the full scope of the present disclosure consistent with the language of the claims.

Reference to an element in the singular does not mean “one and only one” unless specifically stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The terms “may”, “might”, and “can”, as used in this disclosure, often carry certain connotations. For example, “may” refers to a permissible feature that may or may not occur, “might” refers to a feature that probably occurs, and “can” refers to a capability (e.g., capable of). The phrase “For example” often carries a similar connotation to “may” and, therefore, “may” is sometimes excluded from sentences that include “for example” or other similar phrases.

Unless specifically stated otherwise, the term “some” refers to one or more. Combinations such as “at least one of A, B, or C” or “one or more of A, B, or C” include any combination of A, B, and/or C, such as A and B, A and C, B and C, or A and B and C, and may include multiples of A, multiples of B, and/or multiples of C, or may include A only, B only, or C only. Sets should be interpreted as a set of elements where the elements number one or more. Terms or articles such as “a”, “an”, and/or “the” may refer to one of an item, feature, element, etc., that the term or article precedes, or may refer to more than one of said item, feature, element, etc. that the term or article precedes. For example, the recitation “a widget” does not preclude reference to multiples of said widget, as “multiple widgets” necessarily includes “a widget”. Hence, the recitation “a widget” may be interpreted as “at least one widget” or, similarly, interpreted as “one or more widgets”.

Unless otherwise specifically indicated, ordinal terms such as “first” and “second” do not necessarily imply an order in time, sequence, numerical value, etc., but are used to distinguish between different instances of a term or phrase that follows each ordinal term.

Reference numbers, as used in the specification and figures, are sometimes cross-referenced among drawings to denote same or similar features. A feature that is exactly the same in multiple drawings may be labeled with the same reference number in the multiple drawings. A feature that is similar among the multiple drawings, but not exactly the same, may be labeled with reference numbers that have different leading numbers but have one or more of the same trailing numbers (e.g., 206, 306, 406, etc., may refer to similar features in the drawings). Hence, like numbers may refer to like actions.

Structural and functional equivalents to elements of the various aspects described throughout this disclosure that are known or later come to be known to those of ordinary skill in the art are expressly incorporated herein by reference and are encompassed by the claims. The words “module,” “mechanism,” “element,” “device,” and the like may not be a substitute for the word “means.” As such, no claim element is to be construed as a means plus function unless the element is expressly recited using the phrase “means for.” As used herein, the phrase “based on” shall not be construed as a reference to a closed set of information, one or more conditions, one or more factors, or the like. In other words, the phrase “based on A”, where “A” may be information, a condition, a factor, or the like, shall be construed as “based at least on A” unless specifically recited differently.

What is claimed is:

1. An electronic system, comprising:
a printed circuit board (PCB);
a plurality of electronic packages disposed on the PCB and having electrical connections to conductors of the PCB; and
at least one bridge package, each bridge package of the at least one bridge package electrically connecting two adjacent electronic packages of the plurality of electronic packages to thereby facilitate direct communication between the two adjacent electronic packages.

2. The electronic system of claim 1, wherein, for each bridge package, a bridge package is disposed substantially over a gap of two adjacent electronic packages.

3. The electronic system of claim 1, wherein the two adjacent electronic packages are connected through bridge interconnects of the bridge package, and wherein the bridge interconnects directly connect with first-level interconnects of the two adjacent electronic packages on the front sides of substrates of the two adjacent electronic packages.

4. The electronic system of claim 1, wherein each bridge package is coreless.

5. The electronic system of claim 1, wherein each bridge package includes a core.

6. The electronic system of claim 1, wherein each bridge package is made from same material as that of a substrate of an electronic package of the plurality of electronic packages.

7. The electronic system of claim 1, wherein each bridge package is made from different material as that of a substrate of an electronic package of the plurality of electronic packages.

8. A method of fabricating an electronic system, comprising:
disposing a plurality of electronic packages on a printed circuit board (PCB), the plurality of electronic packages having electrical connections to conductors of the PCB; and
disposing at least one bridge package, each bridge package of the at least one bridge package electrically connecting two adjacent electronic packages of the plurality of electronic packages to thereby facilitate direct communication between the two adjacent electronic packages.

9. The method of claim 8, wherein the disposing at least one bridge package comprises:
for each bridge package,
disposing a bridge package substantially over a gap of two adjacent electronic packages;
electrically connecting the bridge package with a first electronic package of the two adjacent electronic packages; and
electrically connecting the bridge package with a second electronic package of the two adjacent electronic packages.

10. The method of claim 8, wherein, for each bridge package, a bridge package is disposed substantially over a gap of two adjacent electronic packages.

11. The method of claim 8, wherein the two adjacent electronic packages are connected through bridge interconnects of the bridge package, and wherein the bridge interconnects directly connect with first-level interconnects of the two adjacent electronic packages on the front sides of substrates of the two adjacent electronic packages.

12. The method of claim 8, wherein each bridge package is coreless.

13. The method of claim 8, wherein each bridge package includes a core.

14. The method of claim 8, wherein each bridge package is made from same material as that of a substrate of an electronic package of the plurality of electronic packages.

15. The method of claim 8, wherein each bridge package is made from different material as that of a substrate of an electronic package of the plurality of electronic packages.
